(19) United States
(12) Patent Application Publication
(10) Pub. No.: US 2012/0257335 A1
(43) Pub. Date: Oct. 11, 2012

(54) FLAT-SCREEN DISPLAY DEVICE

(75) Inventors: Akio IWAI, Osaka (JP); Shinichiro SAKAMOTO, Osaka (JP)

(73) Assignee: FUNAI ELECTRIC CO., LTD., Osaka (JP)

(21) Appl. No.: 13/434,509

(22) Filed: Mar. 29, 2012

(30) Foreign Application Priority Data
Apr. 7, 2011 (JP) 2011-085760
Apr. 7, 2011 (JP) 2011-085761

(51) Int. Cl. H05K 7/00

(52) U.S. Cl. 361/679.01

(57) ABSTRACT

A flat-screen display device includes a cabinet, a display module, a wall bracket, a boss and a linking member. The cabinet has front and rear cabinet components. The front and rear cabinet components define an interior of the cabinet therebetween. The wall bracket has a bolt insertion hole. The boss protrudes from the rear wall of the rear cabinet component towards the interior of the cabinet. The boss has a tubular portion and a bottom portion. The linking member couples the wall bracket to the rear wall of the rear cabinet component. The linking member has a linking bolt and a tubular nut with a male thread on an outer peripheral face of the tubular nut. The linking bolt is disposed through the bolt insertion hole of the wall bracket and fastened to the tubular nut. The tubular nut is fastened to the tubular portion of the boss.

### CROSS-REFERENCE TO RELATED APPLICATIONS

This application claims priority to Japanese Patent Application Nos. 2011-085760 filed on Apr. 7, 2011 and 2011-085761 filed on Apr. 7, 2011. The entire disclosures of Japanese Patent Application Nos. 2011-085760 and 20111-085761 are hereby incorporated herein by reference.

### BACKGROUND

1. Field of the Invention

The present invention generally relates to a flat-screen display device. More specifically, the present invention relates to a flat-screen display device with a wall bracket.

2. Background Information

A conventional wall mounted liquid crystal television set has a cabinet, a liquid crystal module, a control board with various electrical parts, a plurality of linking members, and a wall bracket. The cabinet is made of a synthetic resin. The cabinet has a front cabinet and a rear cabinet. The liquid crystal module is disposed on the front cabinet inside this cabinet. The electrical parts, such as capacitors and resistors, are provided to the control board. The control board includes a printed wiring board. The control board is attached to the liquid crystal module. The wall bracket is affixed by the linking members in the center of the rear cabinet. The wall bracket is engaged with hooks on a wall.

The wall bracket has a U-shaped bracket main body and a pair of side plates that are bent out to the side from both edges of this bracket main body. Latching holes for latching the hooks are made in the bracket main body, and bolt insertion holes are made in the side plates.

The linking members each have a linking bracket, a fastening bolt and a linking bolt. The linking bracket is made of sheet metal. The fastening bolt fastens the linking bracket to the rear cabinet. The linking bolt links the linking bracket to the wall bracket. The linking brackets each have a proximal end plate that abuts the rear face of the rear cabinet, a middle plate that is bent at a right angle from the edge of the proximal end plate, and a distal end plate that is parallel to the proximal end plate and is bent from the edge of the middle plate. A bottomed, cylindrical nut protrudes integrally from the center of the proximal end plate. Through-holes are made in the rear cabinet opposite the nuts. Bolt insertion holes are made in the center of the distal end plates. Bosses protrude integrally from the rear face of the rear cabinet opposite the bolt insertion holes.

The procedure for attaching the wall mount liquid crystal television set will now be described. The fastening bolts are passed through the bolt insertion holes in the linking brackets and threaded into center holes in the bosses. The linking brackets are fastened to the rear face of the rear cabinet. Then, the linking bolts are threaded into the nuts through the bolt insertion holes in the wall bracket and the through-holes in the rear cabinet. The wall bracket is affixed in the center of the rear cabinet. After this, the latching holes in the wall bracket are latched onto the hooks on the wall. Another conventional display device is also known (see Japanese Laid-Open Patent Application Publication No. 2007-233018, for example).

### SUMMARY

With the conventional wall mounted liquid crystal television set, the linking brackets, the fastening bolts and the linking bolts have complicated shapes. The linking brackets, the fastening bolts and the linking bolts are required to affix the wall bracket to the rear cabinet. Because so many parts are needed, the cost is higher.

Furthermore, since the linking brackets and the fastening bolts are exposed inside the cabinet, a safe distance must be ensured between the electrical parts and the linking brackets and fastening bolts, as defined by safety standards. This hinders the goal of making the cabinet thinner.

Moreover, since the rear cabinet is interposed between the wall bracket and the nuts. Thus, there is a large gap between the two. This results in weak affixing strength of the wall bracket with respect to the rear cabinet.

In view of this, it has been discovered that it is possible to affix the wall bracket in the center of the of the rear cabinet by threading insert nuts into communicating holes in the rear cabinet and threading the linking bolts into these insert nuts. This does reduce the number of parts. However, since the air inside and outside the cabinet communicates through the threaded holes of the insert nuts, there is the risk that dust or other foreign matter will work its way into the cabinet through the threaded holes of the insert nuts. Furthermore, since the insert nuts are exposed on the inside of the cabinet, a safe distance must be ensured between the electrical parts and the insert nuts, as defined by safety standards. This again hinders the goal of making the cabinet thinner.

An improved flat-screen display device was conceived in light of the above-mentioned problem. One object of the present disclosure is to provide a flat-screen display device with which a cabinet is tightly fixed to a wall bracket while maintaining the cabinet thin.

In accordance with one aspect of the present disclosure, a flat-screen display device includes a cabinet, a display module, a wall bracket, a boss and a linking member. The cabinet has front and rear cabinet components. The front and rear cabinet components define an interior of the cabinet therebetween. The display module is disposed in the interior of the cabinet. The wall bracket is attached to a rear wall of the rear cabinet component. The wall bracket has a bolt insertion hole. The boss protrudes from the rear wall of the rear cabinet component towards the interior of the cabinet. The boss has a tubular portion and a bottom portion that is disposed on a distal end of the tubular portion. The linking member couples the wall bracket to the rear wall of the rear cabinet component. The linking member has a linking bolt and a tubular nut with a male thread on an outer peripheral face of the tubular nut. The linking bolt is disposed through the bolt insertion hole of the wall bracket and fastened to the tubular nut. The tubular nut is fastened to the tubular portion of the boss.

These and other objects, features, aspects and advantages will become apparent to those skilled in the art from the following detailed description, which, taken in conjunction with the annexed drawings, discloses a preferred embodiment.

### BRIEF DESCRIPTION OF THE DRAWINGS

Referring now to the attached drawings which form a part of this original disclosure:

FIG. 1 is a rear elevational view of a flat-screen display device in accordance with a first embodiment;

FIG. 2 is a cross sectional view of the flat-screen display device illustrated in FIG. 1, taken along line in FIG. 1;

FIG. 3 is a rear perspective view of a rear cabinet of the flat-screen display device illustrated in FIG. 1;

FIG. 4 is a partial, enlarged cross sectional view of an encircled portion IV in FIG. 2, illustrating an attachment of a linking portion and a wall bracket of the flat-screen display device illustrated in FIG. 1;

FIG. 5 is an exploded perspective view of the linking portion of the flat-screen display device illustrated in FIG. 2, illustrating an attachment of the linking portion relative to the rear cabinet of the flat-screen display device;

FIG. 6 is a cross sectional view of a flat-screen display device in accordance with a second embodiment;

FIG. 7 is a rear perspective view of a rear cabinet of the flat-screen display device illustrated in FIG. 6;

FIG. 8 is a partial, enlarged cross sectional view of an encircled portion VIII in FIG. 6, illustrating an attachment of a linking portion and a wall bracket of the flat-screen display device illustrated in FIG. 6;

FIG. 9 is an exploded perspective view of the linking portion of the flat-screen display device illustrated in FIG. 6, illustrating an attachment of the linking portion relative to the rear cabinet of the flat-screen display device;

FIG. 10A is an enlarged cross sectional view of a tubular nut of the linking portion and a pocket of the flat-screen display device illustrated in FIG. 6, illustrating a first stage of an attachment procedure of the tubular nut relative to the pocket, with the tubular nut aligned relative to the pocket;

FIG. 10B is an enlarged cross sectional view of the tubular nut and the pocket of the flat-screen display device illustrated in FIG. 6, illustrating a second stage of the attachment procedure of the tubular nut relative to the pocket, with the tubular nut inserted into the pocket;

FIG. 10C is an enlarged cross sectional view of the tubular nut and the pocket of the flat-screen display device illustrated in FIG. 6, illustrating a third stage of the attachment procedure of the tubular nut relative to the pocket, with the tubular nut threaded into the pocket;

FIG. 10D is an enlarged cross sectional view of a tubular nut and a pocket of a modified example, illustrating a first stage of an attachment procedure of the tubular nut relative to the pocket, with the tubular nut aligned relative to the pocket;

FIG. 10E is an enlarged cross sectional view of the tubular nut and the pocket of the modified example, illustrating a second stage of the attachment procedure of the tubular nut relative to the pocket, with the tubular nut inserted into the pocket; and

FIG. 10F is an enlarged cross sectional view of the tubular nut and the pocket of the modified example, illustrating a third stage of the attachment procedure of the tubular nut relative to the pocket, with the tubular nut threaded into the pocket.

### DETAILED DESCRIPTION OF EMBODIMENTS

Selected embodiments will now be explained with reference to the drawings. It will be apparent to those skilled in the art from these disclosures that the following descriptions of the selected embodiments are provided for illustration only and not for the purpose of limiting the invention as defined by the appended claims and their equivalents.

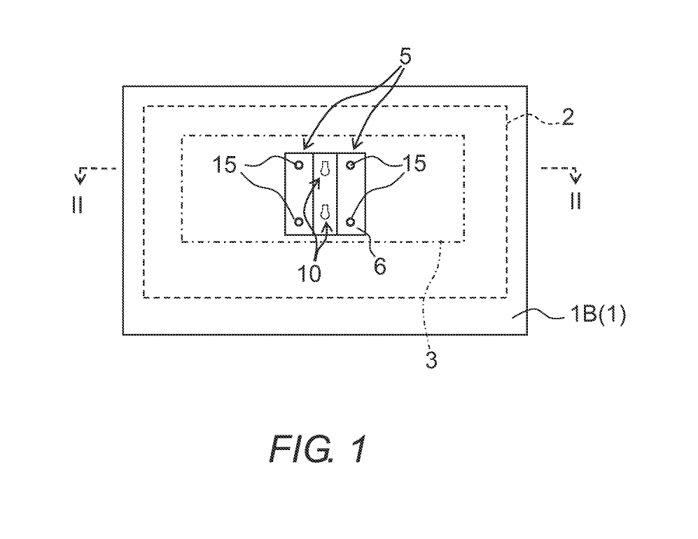

As shown in FIGS. 1 to 5, a flat-screen display device has a cabinet 1, a liquid crystal module 2 (e.g., display module or display device main body), a control board 3 with various electrical parts 4 (e.g., electrical components), a plurality of (four in FIG. 1) linking members 5, and a wall bracket 6. The cabinet 1 is made of a synthetic resin. The cabinet 1 has a front cabinet 1A (e.g., front cabinet component) and a rear cabinet 1B (e.g., rear cabinet component). The front and rear cabinets 1A and 1B define an interior of the cabinet 1 therebetween. The liquid crystal module 2 is disposed on the front cabinet 1A inside this cabinet 1. The electrical parts 4, such as capacitors and resistors, are provided to the control board 3. The control board 3 includes a printed wiring board. The control board 3 is attached to the liquid crystal module 2. The wall bracket 6 is affixed by the linking members 5 in the center of a rear wall 30 of the rear cabinet 1B. In other words, the linking members 5 couple the wall bracket 6 to the rear wall 30 of the rear cabinet 1B. The wall bracket 6 is engaged with hooks 8 that are fixedly mounted on a wall 7.

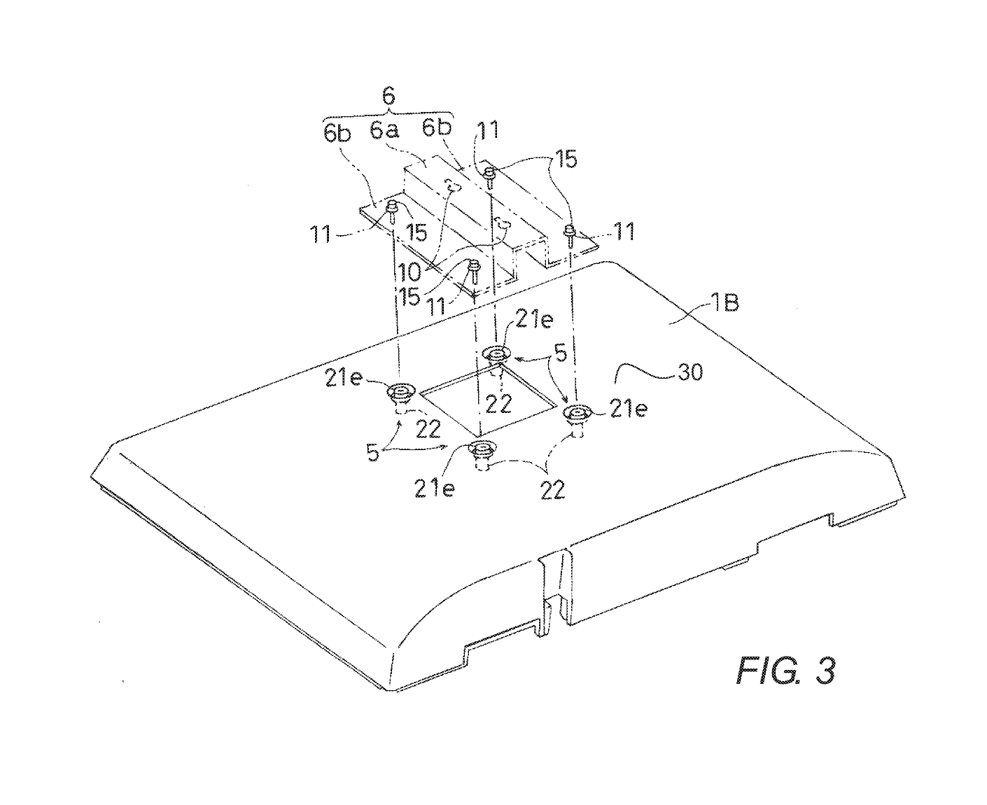

As shown in FIG. 3, the wall bracket 6 has a U-shaped bracket main body 6a and a pair of side plates 6b that are bent out to the side from both edges of this bracket main body 6a. Latching holes 10 for latching the hooks 8 are made in the bracket main body 6a, and bolt insertion holes 11 are made in the side plates 6b.

As shown in FIGS. 1 to 3, the flat-screen display device is a wall mounted liquid crystal television set or a liquid crystal monitor, for example. The linking members 5 each have a linking bolt 15 and a tubular nut 21. The linking bolts 15 are disposed through the bolt insertion holes 11 in the wall bracket 6, respectively, and are threaded into the tubular nuts 21, respectively. The rear cabinet 1B has a plurality of bottomed tubular pockets 22 (e.g., boss). The pockets 22 are integrally molded at a specific spacing and at suitable locations on the rear wall 30 of the rear cabinet 1B. The pockets 22 protrude from the rear wall 30 of the rear cabinet 113 towards the interior of the cabinet 1. The rear cabinet 113 further has a plurality of recesses 23 (e.g., recess portions). The inside diameter R of the recesses 23 is larger than the inside diameter d of the pockets 22, respectively. The recesses 23 are formed around the edges of the openings of the pockets 22, respectively.

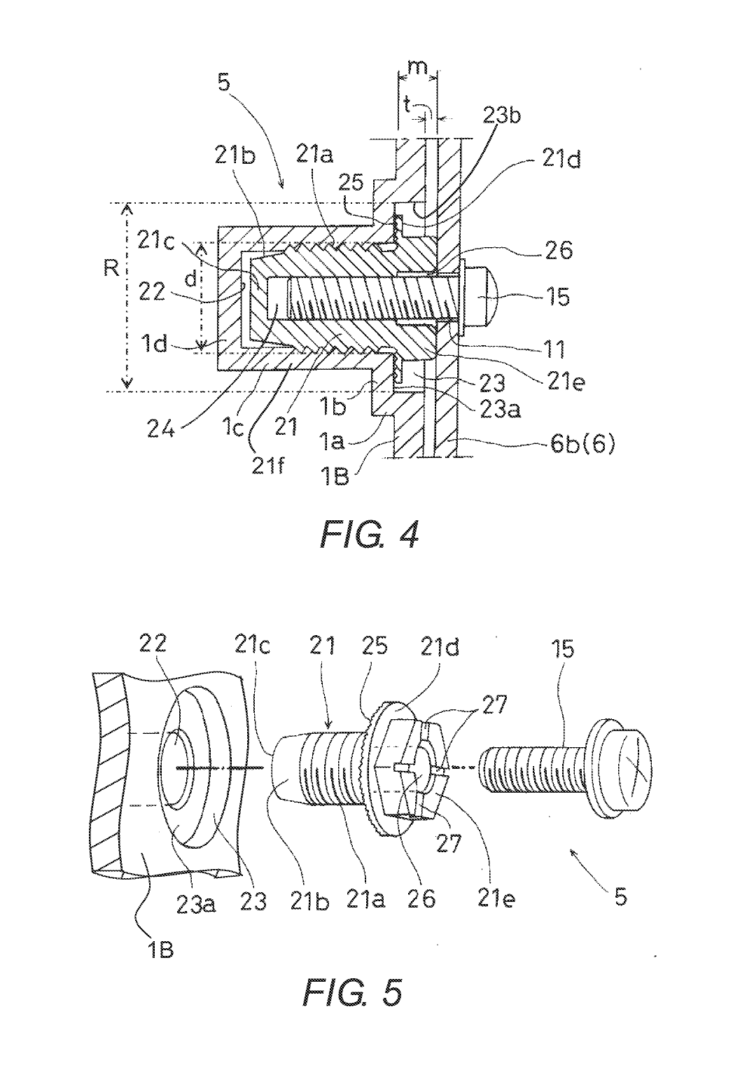

As shown in FIGS. 4 and 5, the recesses 23 are each surrounded by a peripheral wall component 1a and a bottom wall component 1b. The peripheral wall components 1a are molded integrally with the rear cabinet 1B. The bottom wall components 1b are molded integrally with the peripheral wall components 1a. The bottom wall components 1b each have a cylindrical bottom face 23a. The peripheral wall components 1a each have an inner peripheral face 23b. The cylindrical bottom faces 23a and the inner peripheral faces 23b define the recesses 23, respectively. The pockets 22 are each surrounded by a cylindrical wall component 1.c (e.g., tubular portion) and a bottom wall component 1d (e.g., bottom portion). The cylindrical wall components 1c protrude integrally from the center of the bottom wall component 1b of the recess 23 and protrude into the cabinet 1. The bottom wall components 1d are molded integrally with the cylindrical wall components 1c. The bottom wall components 1d are disposed on distal ends of the cylindrical wall components 1c, respectively. The inside diameter R of the inner peripheral faces 23b is larger than the inside diameter d of the cylindrical wall components 1c of the pockets 22. The recesses 23 are arranged relative to the pockets 22 such that the cylindrical bottom faces 23a radially extend from circular edges of openings defined by the cylindrical wall components 1c, respectively. The recesses 23 and the pockets 22 are isolated from the inside of the cabinet 1. Specifically, interiors of the recesses 23 and the pockets 22 do not directly communicate with the interior of the cabinet 1 at locations of the recesses 23 and the pockets 22.

As shown in FIGS. 4 and 5, the tubular nuts 21 each have a male thread 21a, a distal end outer peripheral face 21b, a bottom wall component 21c (e.g., bottom section), a flange 21d, a head 21.e, and a tubular section 21f. The tubular nuts 21 are identical to each other. The tubular nut 21 is integrally formed as a one-piece, unitary member. The tubular nut 21 is made of metal, or hard resin material. The male thread 21a is formed around an outer peripheral face of the tubular section 21f of the tubular nut 21. The distal end outer peripheral face 21b is formed in a tapering shape to form a tapered distal end of the tubular nut 21. The bottom wall component 21c closes off the inner end of a threaded hole 24 defined by the tubular section 21f of the tubular nut 21. The bottom wall component 21c is disposed on a distal end of the tubular section 21f. The bottom wall component 21c is formed integrally with the tubular nut 21. The flange 21.d is opposite the bottom face 23a of the recess 23. The flange 21d is formed integrally with the proximal end outer peripheral face (e.g., axial end portion) of the tubular nut 21. Anti-slip grooves 25 are formed in a contact face of the flange 21d opposite the recess 23. The tubular nut 21 is threaded into the pocket 22 such that the contact face of the flange 21d is disposed opposite and pressed against the bottom face 23a of the recess 23. The head 21e with a polyhedral shape (e.g., hexagonal in FIG. 5) is formed integrally with the proximal end of the tubular nut 21. A through-hole 26 is made in the center of the head 21e concentrically with the threaded hole 24 and in a larger diameter than the threaded hole 24. A cross-shaped (or straight) manipulation groove 27 is formed in the end face of the head 21e. When the tubular nut 21 is threaded into the pocket 22, the head 21e is set to protrude outward by a slight distance t from the recess 23 as shown in FIG. 4.

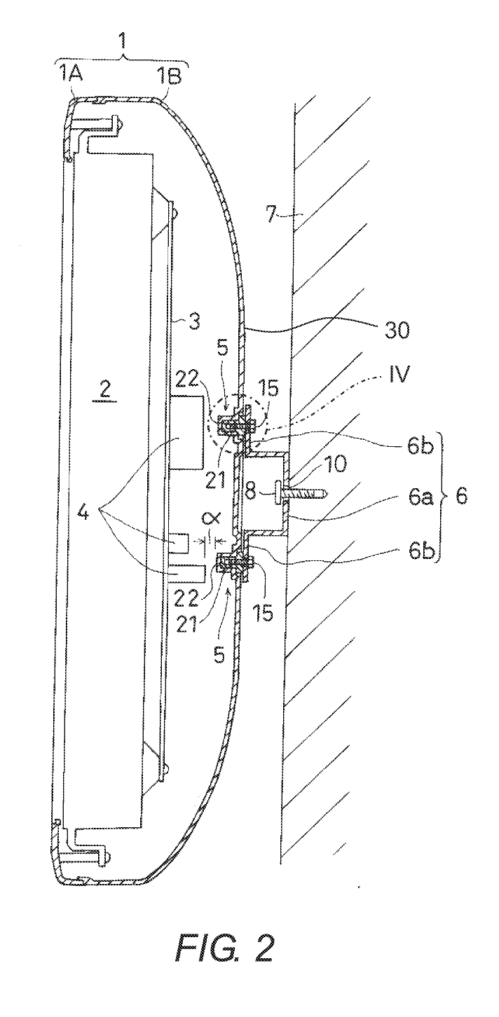

The procedure for attaching the flat-panel display device will now be described. As shown in FIGS. 4 and 5, the distal end outer peripheral faces 21b of the tubular nuts 21 are inserted into the pockets 22, respectively. A wrench or other such tool is engaged with each of the heads 21e, or a cross-head screwdriver (or flat-head screwdriver) is engaged in each of the manipulation grooves 27. The tubular nuts 21 are threaded into the pockets 22, respectively. Consequently, threaded grooves are forcibly formed in the inner peripheral faces of the pockets 22 by the male threads 21a, respectively. The flanges 21d are pressed against the bottom faces 23a of the recesses 23, respectively. Then, the linking bolts 15 are threaded into the threaded holes 24 of the tubular nuts 21 through the bolt insertion holes 11 in the wall bracket 6 and the through-holes 26 in the heads 21e, respectively. The wall bracket 6 is pressed against the heads 21e and affixed in the center of the rear wall 30 of the rear cabinet 1B. After this, as shown in FIG. 2, the latching holes 10 of the wall bracket 6 are latched onto the hooks 8 on the wall 7.

With the above configuration, the linking members 5 each have the tubular nut 21 with the male thread 21a formed around its outer peripheral face, and the linking bolt 15. Since fewer parts are needed, the cost can be reduced.

Also, the tubular nuts 21 are threaded into the bottomed tubular pockets 22 molded integrally at suitable places on the rear wall 30 of the rear cabinet 1B. These bottomed tubular pockets 22 seal the space between the electrical parts 4 of the liquid crystal module 2 and the tubular nuts 21. Thus, the safe distance α between the tubular nuts 21 and the electrical parts 4, as defined by safety standards, can be reduced, thereby meeting the need to make the cabinet 1 thinner.

Furthermore, the inner ends of the threaded holes 24 in the tubular nuts 21 are closed off by the bottom wall components 21c. Even if long linking bolts should accidentally be threaded into these threaded holes 24, the distal ends of these linking bolts will hit the bottom wall component 21c. Thus, the linking bolts cannot be threaded in any further. Therefore, the bottomed tubular pockets 22 will not be damaged by the linking bolts that are too long. Furthermore, the seal provided by these bottomed tubular pockets 22 can be effectively maintained.

Moreover, since the flanges 21d formed integrally at the outer peripheral faces of the proximal ends of the tubular nuts 21 are pressed against the bottom faces 23a of the recesses 23. This keeps the tubular nuts 21 from coming loose from the pockets 22. Furthermore, loosening of the tubular nuts 21 is further prevented by the anti-slip grooves 25 formed on the faces of the flanges 21d opposite the recesses 23.

Also, the work of threading in the tubular nuts 21 can be easily accomplished by engaging a wrench or other such tool with the polyhedral heads 21e formed integrally and concentrically with the proximal ends of the tubular nuts 21, or by engaging a cross-head screwdriver (or a slotted screwdriver) with the manipulation grooves 27 of the heads 21e.

As shown in FIG. 4, since the wall bracket 6 is pressed against the heads 21e of the tubular nuts 21, the gap in between the threaded holes 24 of the tubular nuts 21 and the wall bracket 6 can be reduced. This allows the wall bracket 6 to be affixed securely to the rear cabinet 1B.

### Second Embodiment

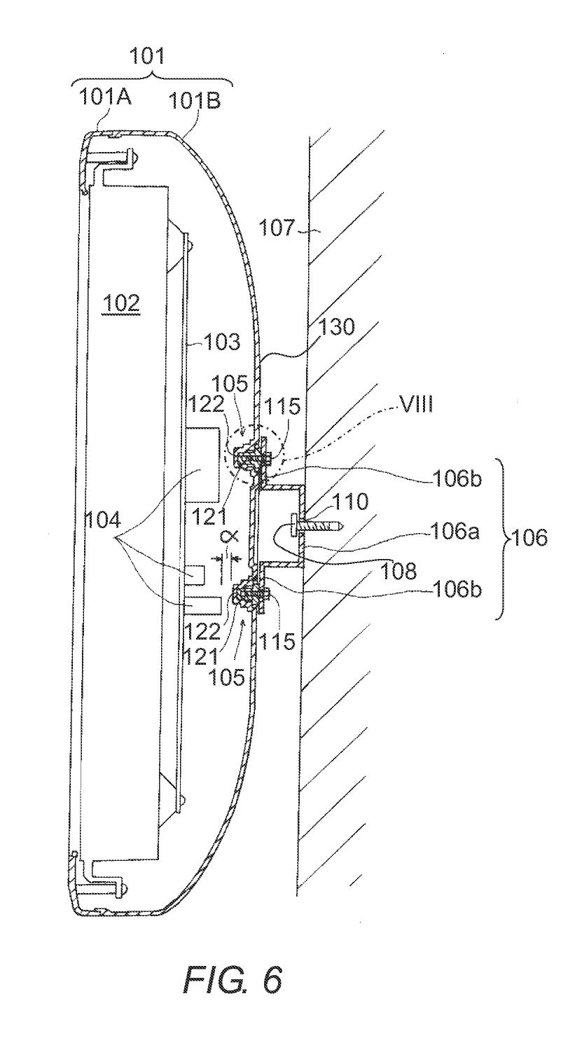

Referring now to FIGS. 6 to 10F, a flat-screen display device with a plurality of modified pockets 122 in accordance with a second embodiment will now be explained.

In view of the similarity between the first and second embodiments, the parts of the second embodiment that are identical to the parts of the first embodiment will be given the same reference numerals as the parts of the first embodiment. Also, parts of this second embodiment that are functionally identical and/or substantially identical to parts of the first embodiment will be given the same reference numerals but with “100” added thereto. In any event, the descriptions of the parts of the second embodiment that are substantially identical to the parts of the first embodiment may be omitted for the sake of brevity. However, it will be apparent to those skilled in the art from this disclosure that the descriptions and illustrations of the first embodiment also apply to this second embodiment, except as discussed and/or illustrated herein.

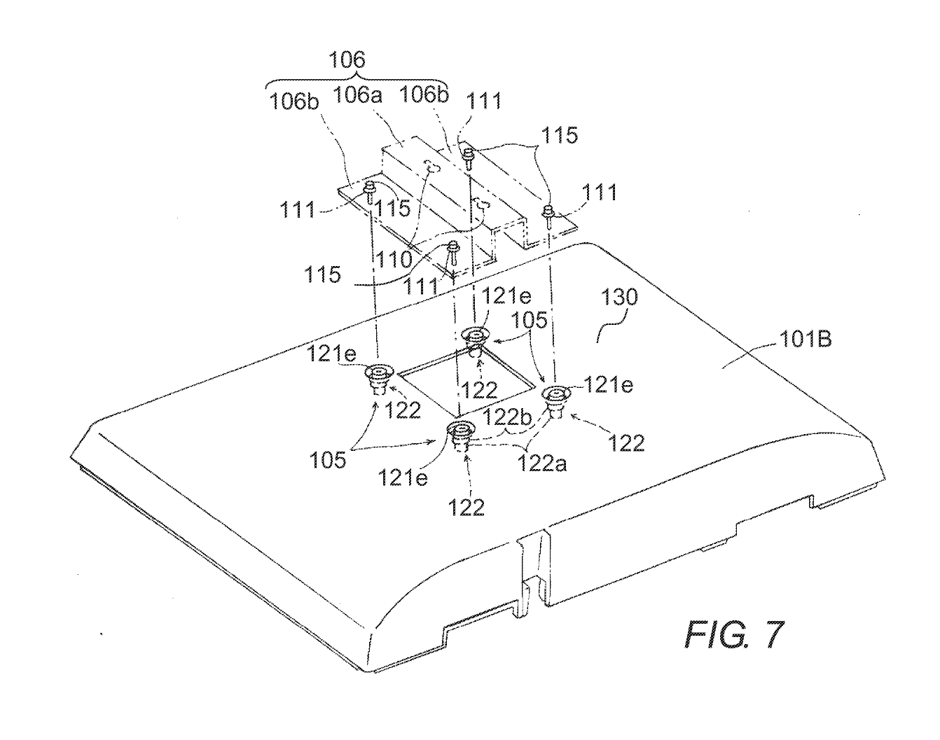

As shown in FIGS. 6 to 10F, the flat-screen display device has a cabinet 101, a liquid crystal module 102 (e.g., display module or display device main body), a control board 103 with various electrical parts 104 (e.g., electrical components), a plurality of (four in FIG. 7) linking members 105, and a wall bracket 106. The cabinet 101 is made of a synthetic resin. The cabinet 101 has a front cabinet 101A (e.g., front cabinet component) and a rear cabinet 10113 (e.g., rear cabinet component). The front and rear cabinets 101A and 101B define an interior of the cabinet 101 therebetween. The liquid crystal module 102 is disposed on the front cabinet 101A inside this cabinet 101. The electrical parts 104, such as capacitors and resistors, are provided to the control board 103. The control board 103 includes a printed wiring board. The control board 103 is attached to the liquid crystal module 102. The wall bracket 106 is affixed by the linking members 105 in the center of a rear wall 130 of the rear cabinet 101B. In other words, the linking members 105 couple the wall bracket 106 to the rear wall 130 of the rear cabinet 101B. The wall bracket 106 is engaged with hooks 108 that are fixedly mounted on a wall 107.

As shown in FIG. 6, the wall bracket 106 has a U-shaped bracket main body 106a and a pair of side plates 106b that are bent out to the side from both edges of this bracket main body 106a. Latching holes 110 for latching the hooks 108 are made in the bracket main body 106a, and bolt insertion holes 111 are made in the side plates 106b.

As shown in FIGS. 6 and 7, the flat-screen display device is a wall mounted liquid crystal television set or a liquid crystal monitor, for example. The linking members 105 each have a linking bolt 115 and a tubular nut 121. The linking bolts 115 are disposed through the bolt insertion holes 111 in the wall bracket 106, respectively, and are threaded into the tubular nuts 121, respectively. The rear cabinet 101B has a plurality of bottomed tubular pockets 122 (e.g., boss). The pockets 122 are integrally molded at a specific spacing and at suitable locations on the rear wall 130 of the rear cabinet 101B. The pockets 122 protrude from the rear wall 130 of the rear cabinet 101B towards the interior of the cabinet 101. The rear cabinet 101B further has a plurality of recesses 123 (e.g., recess portions). The inside diameter R of the recesses 123 is larger than the inside diameter d1 or d2 of the pockets 122, respectively. The recesses 23 are formed around the edges of the openings of the pockets 122, respectively.

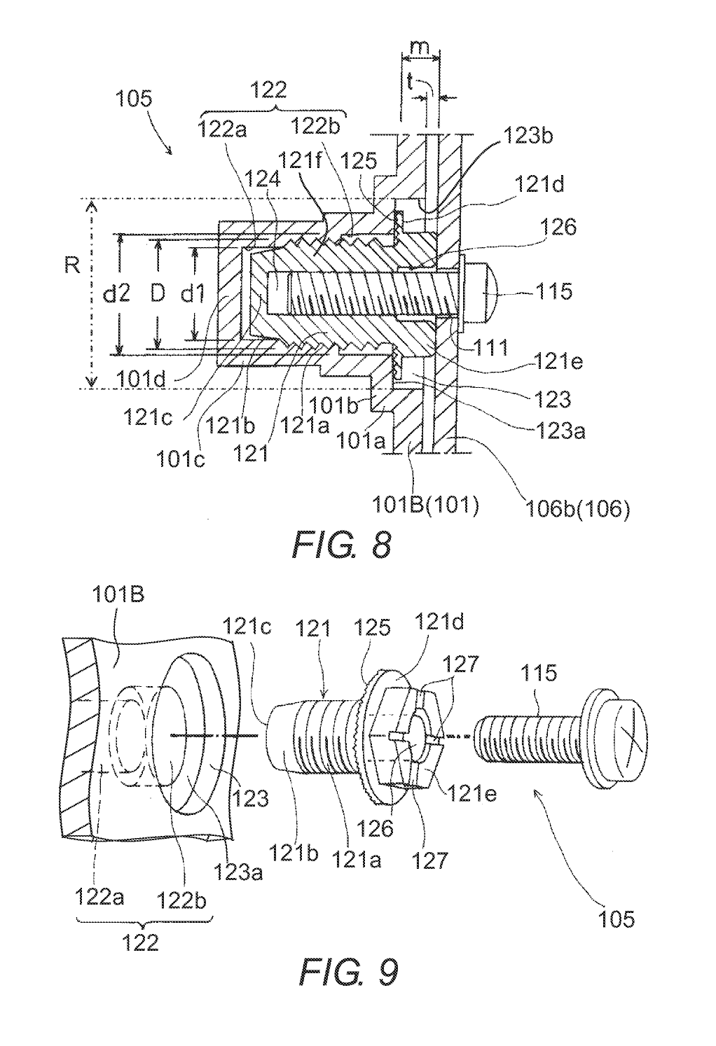

As shown in FIGS. 8 and 9, the recesses 123 are each surrounded by a peripheral wall component 101a and a bottom wall component 101b. The peripheral wall components 1a are molded integrally with the rear cabinet 1019. The bottom wall components 101b are molded integrally with the peripheral wall components 101a. The bottom wall components 101b each have a cylindrical bottom face 123a. The peripheral wall components 101a each have an inner peripheral face 123b. The cylindrical bottom faces 123a and the inner peripheral faces 123b define the recesses 123, respectively. The pockets 122 are each surrounded by a cylindrical wall component 101c (e.g., tubular portion) and a bottom wall component 101d (e.g., bottom portion). The cylindrical wall components 1c protrude integrally from the center of the bottom wall component 101b of the recess 123 and protrude into the cabinet 101. The bottom wall components 101d are molded integrally with the cylindrical wall components 101c. The bottom wall components 101d are disposed on distal ends of the cylindrical wall components 101c, respectively. The inside diameter R of the inner peripheral faces 123b is larger than the inside diameter d1 or d2 of the cylindrical wall components 101c of the pockets 122. The recesses 123 are arranged relative to the pockets 122 such that the cylindrical bottom faces 123a radially extend from circular edges of openings defined by the cylindrical wall components 101c, respectively. The recesses 123 and the pockets 122 are isolated from the inside of the cabinet 101. Specifically, interiors of the recesses 123 and the pockets 122 do not directly communicate with the interior of the cabinet 101 at locations of the recesses 123 and the pockets 122.

As shown in FIGS. 8 and 9, the pockets 122 are each divided into an inner end-side small-diameter part 122a (e.g., small diameter section) and an open end-side large-diameter part 122b (e.g., large diameter section). The inner end-side small-diameter part 122a and the open end-side large-diameter part 122b are axially arranged relative to each other. The open end-side large-diameter part 122b is disposed between the inner end-side small-diameter part 122a and the rear wall 130 of the rear cabinet 10113. The inner end-side small-diameter parts 122a have an inside diameter d1 which is smaller than the outside diameter D of male threads 121a of the tubular nuts 121. The open end-side large-diameter parts 122b have an inside diameter d2 which is the same as or slightly larger than (i.e., at least equal to) the outside diameter D of the male threads 121a of the tubular nuts 121 (i.e., d1<D≦d2). The tubular nuts 121 is disposed through the open end-side large-diameter part 122b, and threaded into the inner end-side small-diameter part 122a.

As shown in FIGS. 8 and 9, the tubular nuts 121 each have a male thread 121a, a distal end outer peripheral face 121b, a bottom wall component 121c (e.g., bottom section), a flange 121d, a head 121e and a tubular section 121f. The tubular nuts 121 are identical to each other. The tubular nut 121 is integrally formed as a one-piece, unitary member. The tubular nut 121 is made of metal, or hard resin material. The male thread 121a is formed around an outer peripheral face of the tubular section 121f of the tubular nut 121. The distal end outer peripheral face 121b is formed in a tapering shape to form a tapered distal end of the tubular nut 121. The bottom wall component 121c closes off the inner end of a threaded hole 124 defined by the tubular section 121 of the tubular nut 121. The bottom wall component 121c is disposed on a distal end of the tubular section 121f. The bottom wall component 121c is formed integrally with the tubular nut 121. The flange 121d is opposite the bottom face 123a of the recess 123. The flange 121d is formed integrally with the proximal end outer peripheral face (e.g., axial end portion) of the tubular nut 121. Anti-slip grooves 125 are formed in a contact face of the flange 121d opposite the recess 123. The tubular nut 121 is threaded into the pocket 122 such that the contact face of the flange 121d is disposed opposite and pressed against the bottom face 123a of the recess 123. The head 121e with a polyhedral shape (e.g., hexagonal in FIG. 9) is formed integrally with the proximal end of the tubular nut 121. A through-hole 126 is made in the center of the head 121e concentrically with the threaded hole 124 and in a larger diameter than the threaded hole 124. A cross-shaped (or straight) manipulation groove 127 is formed in the end face of the head 121e. When the tubular nut 121 is threaded into the pocket 122, the head 121e is set to protrude outward by a slight distance t from the recess 123 as shown in FIG. 8.

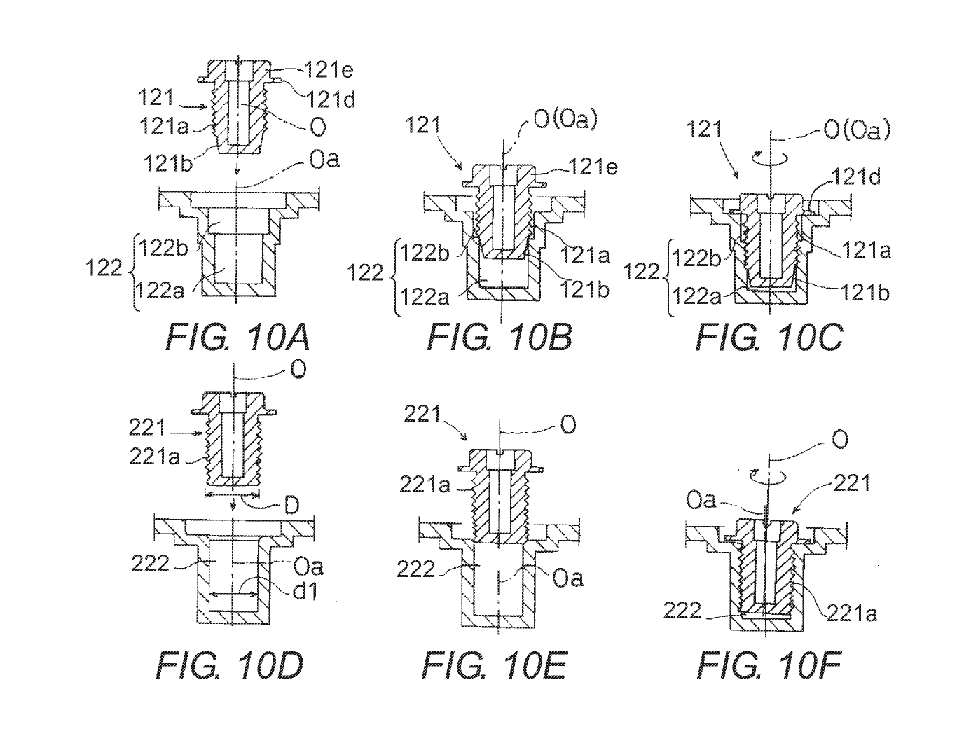

Referring to FIGS. 10D to 10F, a tubular nut 221 and a pocket 122 will be described as a modified example of the tubular nut 121 and the pocket 122. The tubular nut 221 has an inner peripheral face from the inner end to the open end. The inner peripheral face of the tubular nut 221 is formed within the same plane. The inside diameter d1 of the pocket 222 is set to be smaller than the outside diameter D of a male thread 221a of the tubular nut 221 (i.e., d1<D). The distal end of the tubular nut 221 is brought into contact with the pocket 222 from above as shown in FIGS. 10D and 10E, and the tubular nut 221 is threaded into the pocket 222 as shown in FIG. 10F. With this configuration, the tubular nut 221 can be threaded into the pocket 222 at an angle in a state in which the axis O of the tubular nut 221 deviates from the axis Oa of the pocket 222.

In the modified example, it is difficult for the linking bolt 215 to be smoothly threaded into the tubular nut 221 that has been threaded in at an angle. Furthermore, the affixing strength of the wall bracket 106 can also be weaker. In view of this, a jig can be used to guide the tubular nut 221 so that it is threaded straight in. However, the use of a jig drives up the cost.

On the other hand, with the procedure thr attaching the tubular nut 121, the distal ends of the tubular nuts 121 are inserted into the pockets 122 from above, respectively, as shown in FIG. 10A. The tubular nuts 121 are guided by the open end-side large-diameter parts 122b of the pockets 122, respectively, as shown in FIG. 10B. The distal ends of the tubular nuts 121 are inserted into the inner end-side small-diameter parts 122a of the pockets 122, respectively, and the axes O) of the tubular nuts 121 are aligned concentrically with the axes Oa of the pockets 122, respectively. After this, a wrench or other such tool is engaged with each of the heads 121e, or a cross-head screwdriver (or flat-head screwdriver) is engaged in each of the manipulation grooves 127. The tubular nuts 121 are threaded into the pockets 122, respectively, as shown in FIG. 10C. In other words, the tubular nuts 121 are threaded into the inner end-side small-diameter parts 122a through the open end-side large-diameter parts 122b, respectively. Consequently, threaded grooves are forcibly formed in the inner peripheral faces of the inner end-side small-diameter parts 122a of the pockets 122 by the male threads 121a, respectively. The flanges 121d are pressed against the bottom faces 123a of the recesses 123, respectively. Then, as shown in FIG. 8, the linking bolts 115 are threaded into the threaded holes 124 of the tubular nuts 121 through the bolt insertion holes 111 in the wall bracket 106 and the through-holes 126 in the heads 121e, respectively. The wall bracket 106 is pressed against the heads 121e and affixed in the center of the rear wall 130 of the rear cabinet 101B. After this, as shown in FIG. 6, the latching holes 110 of the wall bracket 106 are latched onto the hooks 108 on the wall 107.

With the above configuration, the linking members 105 each have the tubular not 121 with the male thread 121a formed around its outer peripheral face, and the linking bolt 115. Since fewer parts are needed, the cost can be reduced.

Also, when the tubular nuts 121 are pushed into the bottomed tubular pockets 122, the open end-side large-diameter parts 122b of the pockets 122 serve as guides to position the tubular nuts 121 concentrically with respect to the inner end-side small-diameter parts 122a of the pockets 122. Thus, the tubular nuts 121 can be threaded straight into the inner end-side small-diameter parts 122a of the pockets 122 as intended. This allows the threading of the linking bolts 115 into the tubular nuts 121 also to proceed as intended, and the wall bracket 106 to be properly affixed to the rear cabinet 101B.

Furthermore, the space between the electrical parts 104 of the liquid crystal module 102 and the tubular nuts 121 is sealed by the bottomed tubular pockets 122. Thus, the safe distance α between the tubular nuts 121 and linking bolts 115 and the electrical parts 104, as defined by safety standards, can be reduced, thereby meeting the need to make the cabinet thinner.

In addition, the distal ends of the tubular nuts 121 taper toward the end. When the distal ends of the tubular nuts 121 are pushed into the inner end-side small-diameter parts 122a of the pockets 122, the tubular nuts 121 can be positioned more concentrically with respect to the inner end-side small-diameter parts 122a.

Further, the inner ends of the threaded holes 124 in the tubular nuts 121 are closed off by the bottom wall components 121c. Even if long linking bolts should accidentally be threaded into these threaded holes 124, the distal ends of these linking bolts will hit the bottom wall component 121c. Thus, the linking bolts cannot be threaded in any further. Therefore, the bottomed tubular pockets 122 will not be damaged by the bolts that are too long. Furthermore, the seal provided by these bottomed tubular pockets 122 can be effectively maintained.

Moreover, since the flanges 121d formed integrally at the outer peripheral faces of the proximal ends of the tubular nuts 121 are pressed against the bottom faces 123a of the recesses 123. This keeps the tubular nuts 121 from coming loose from the pockets 122. Furthermore, loosening of the tubular nuts 121 is further prevented by the anti-slip grooves 125 formed on the faces of the flanges 121d opposite the recesses 123.

Also, the work of threading in the tubular nuts 121 can be easily accomplished by engaging a wrench or other such tool with the polyhedral heads 121e formed integrally and concentrically with the proximal ends of the tubular nuts 121, or by engaging a cross-head screwdriver (or a slotted screwdriver) with the manipulation grooves 127 of the heads 121e.

As shown in FIG. 8, since the wall bracket 106 is pressed against the heads 121e of the tubular nuts 121, the gap m between the threaded holes 124 of the tubular nuts 121 and the wall bracket 106 can be reduced. This allows the wall bracket 106 to be affixed securely to the rear cabinet 101B.

### GENERAL INTERPRETATION OF TERMS

In understanding the scope of the present invention, the term “comprising” and its derivatives, as used herein, are intended to be open ended terms that specify the presence of the stated features, elements, components and groups, but do not exclude the presence of other unstated features, elements, components and groups. The foregoing also applies to words having similar meanings such as the terms, “including”, “having” and their derivatives. Also, the terms “part,” “section,” “portion,” “member” or “element” when used in the singular can have the dual meaning of a single part or a plurality of parts.

While selected embodiments have been chosen to illustrate the present invention, it will be apparent to those skilled in the art from these disclosures that various changes and modifications can be made herein without departing from the scope of the invention as defined in the appended claims. Furthermore, the foregoing descriptions of the selected embodiment according to the present invention are provided for illustration only, and not for the purpose of limiting the invention as defined by the appended claims and their equivalents.

What is claimed is:

1. A flat-screen display device comprising:
a cabinet having front and rear cabinet components, the front and rear cabinet components defining an interior of the cabinet therebetween;
a display module disposed in the interior of the cabinet;
a wall bracket attached to a rear wall of the rear cabinet component, the wall bracket having a bolt insertion hole;
a boss protruding from the rear wall of the rear cabinet component towards the interior of the cabinet, the boss having a tubular portion and a bottom portion that is disposed on a distal end of the tubular portion; and
a linking member coupling the wall bracket to the rear wall of the rear cabinet component, the linking member having a linking bolt and a tubular nut with a male thread on an outer peripheral face of the tubular nut, the linking bolt being disposed through the bolt insertion hole of the wall bracket and fastened to the tubular nut, the tubular nut being fastened to the tubular portion of the boss.

2. The flat-screen display device according to claim 1, wherein
the tubular nut of the linking member includes a tubular section that defines a threaded hole into which the linking bolt is threaded, and a bottom section that is disposed on a distal end of the tubular section, the tubular section and the bottom section being integrally formed as a one-piece, unitary member.

3. The flat-screen display device according to claim 1, wherein
the rear wall of the rear cabinet component of the cabinet includes a recess portion with an inner peripheral face and a cylindrical bottom face, the inner peripheral face has an inside diameter that is larger than an inside diameter of the tubular portion of the boss, the recess portion being arranged relative to the boss such that the cylindrical bottom face of the recess portion radially extending from an circular edge of an opening defined by the tubular portion.

4. The flat-screen display device according to claim 3, wherein
the tubular nut of the linking member includes a flange with a contact face, the flange being disposed around an axial end portion of the outer peripheral face of the tubular nut, the tubular nut being threaded into the boss such that the contact face of the flange is disposed opposite and pressed against the cylindrical bottom face of the recess.

5. The flat-screen display device according to claim 4, wherein
the contact face of the flange has a plurality of anti-slip grooves.

6. The flat-screen display device according to claim 1, wherein
the tubular nut of the linking member includes a polyhedral head with a through-hole, the through-hole of the head being concentrically disposed relative to a threaded hole of the tubular nut, the through-hole of the head having a larger diameter than the threaded hole of the tubular nut.

7. The flat-screen display device according to claim 6, wherein
the head of the tubular nut of the linking member includes one of a straight manipulation groove and a cross-shaped manipulation groove on an end face of the head.

8. The flat-screen display device according to claim 1, wherein
the front and rear cabinet components are made of a synthetic resin.

9. The flat-screen display device according to claim 1, further comprising
a control board with an electrical component, the control board being attached to the display module.

10. The flat-screen display device according to claim 1, wherein
the tubular portion of the boss further includes a small diameter section and a large diameter section, the small diameter section having an inside diameter that is smaller than an outside diameter of the male thread of the tubular nut, the large diameter section having an inside diameter that is at least equal to the outside diameter of the male thread of the tubular nut, the tubular nut being disposed through the large diameter section of the tubular portion and threaded into the small diameter section of the tubular portion.

11. The flat-screen display device according to claim 10, wherein
the small and large diameter sections of the tubular portion of the boss are axially arranged relative to each other, the large diameter section being disposed between the small diameter section and the rear wall of the rear cabinet component.

12. The flat-screen display device according to claim 10, wherein
the tubular nut of the linking member includes a tapered distal end.

13. The flat-screen display device according to claim 10, wherein
the tubular nut of the linking member includes a tubular section that defines a threaded hole into which the linking bolt is threaded, and a bottom section that is disposed on a distal end of the tubular section, the tubular section and the bottom section being integrally formed as a one-piece, unitary member.

14. The flat-screen display device according to claim 10, wherein
the rear wall of the rear cabinet component of the cabinet includes a recess portion with an inner peripheral face and a cylindrical bottom face, the inner peripheral face has an inside diameter that is larger than an inside diameter of the tubular portion of the boss, the recess portion being arranged relative to the boss such that the cylindrical bottom face of the recess portion radially extending from an circular edge of an opening defined by the tubular portion.

15. The flat-screen display device according to claim 14, wherein
the tubular nut of the linking member includes a flange with a contact face, the flange being disposed around an axial end portion of the outer peripheral face of the tubular nut, the tubular nut being threaded into the boss such that the contact face of the flange is disposed opposite and pressed against the cylindrical bottom face of the recess.

16. The flat-screen display device according to claim 15, wherein
the contact face of the flange has a plurality of anti-slip grooves.

17. The flat-screen display device according to claim 10, wherein
the tubular nut of the linking member includes a polyhedral head with a through-hole, the through-hole of the head being concentrically disposed relative to a threaded hole of the tubular nut, the through-hole of the head having a larger diameter than the threaded hole of the tubular nut.

18. The flat-screen display device according to claim 17, wherein
the head of the tubular nut of the linking member includes one of a straight manipulation groove and a cross-shaped manipulation groove on an end face of the head.

19. The flat-screen display device according to claim 10, wherein
the front and rear cabinet components are made of a synthetic resin.

20. The flat-screen display device according to claim 10, further comprising
a control board with an electrical component, the control board being attached to the display module.
